(19) United States
(12) Patent Application Publication
(10) Pub. No.: US 2017/0176811 A1
(43) Pub. Date: Jun. 22, 2017

(54) COLOR PHOTORESIST AND ITS USE, COLOR FILM SUBSTRATE, DISPLAY PANEL AND LIQUID CRYSTAL DISPLAY

(71) Applicant: Boe Technology Group Co., Ltd., Beijing (CN)

(72) Inventors: Xin Gu, Beijing (CN); Yonglian Qi, Beijing (CN); Bin Zhang, Beijing (CN); Tingting Zhou, Beijing (CN); Dini Xie, Beijing (CN)

(21) Appl. No.: 15/038,527

(22) PCT Filed: Oct. 15, 2015
(86) PCT No.: PCT/CN2015/091967

§ 371 Date: May 23, 2016

(30) Foreign Application Priority Data
Jun. 24, 2015 (CN) 201510354655.3

(51) Int. Cl. G02F 1/1335; C09K 11/88; C09K 11/56; C09K 11/66; C09K 11/02; C08F 265/06; C08K 3/30; C08K 7/18; C08K 3/34; C08F 267/04; G03F 7/00; G03F 7/031; G03F 7/033; G03F 7/004; G02B 5/20

(52) U.S. Cl. CPC G02F 1/133514; G02F 1/133516; G02B 5/206; C09K 11/883; C09K 11/565; C09K 11/66; C09K 11/025; C08F 265/06; C08K 3/30; C08K 7/18; C08K 3/34; C08F 267/04; G03F 7/0005; G03F 7/031; G03F 7/033; G03F 7/0042; G02F 2202/36; B82Y 20/00

(57) ABSTRACT

The present invention discloses a color photoresist and its use, a color film substrate, a display panel and a liquid crystal display, which pertains to the field of photosensitive materials. The color photoresist comprises a photoinitiator and QDs. The photoinitiator is a first photoinitiator containing no electron-rich group or a second photoinitiator containing an electron-rich group. The second photoinitiator comprises a conjugation structure, and the conjugation structure consists of the electron-rich group and an adjacent group of the electron-rich group. The color photoresist provided in embodiments of the present invention contains QDs which emit light normally. The color film substrate prepared by using the color photoresist has a high color gamut and can effectively improve the picture quality of the liquid crystal display.

### RELATED APPLICATIONS

The present application is the U.S. national phase entry of PCT/CN2015/091967, with an international filing date of Oct. 15, 2015, which claims the benefit of Chinese Patent Application No. 201510354655.3, filed on Jun. 24, 2015, the entire disclosures of which are incorporated herein by reference.

### TECHNICAL FIELD

The present invention relates to the field of photosensitive materials, and particularly to a color photoresist and its use, a color film substrate, a display panel and a liquid crystal display.

### BACKGROUND ART

Quantum dots (QDs) are nanoparticles with a stable diameter in a range of 2-20 nm, which are generally spherical or quasi-spherical, and are made, for example, of a semiconductor material. QDs are nano-scale aggregates of atoms and molecules, which are composed of one semiconductor material (e.g. IIB-VIA compound semiconductors of CdS, CdSe, CdTe, ZnSe, etc, IIIA-VA compound semiconductors of InP, InAs, etc, or elemental semiconductors), or composed of two or more semiconductor materials. As a novel semiconductor nanomaterial, the semiconductor QDs have advantages of wide and continuously distributed excitation spectrums, narrow and symmetrical emission spectrums, tunable color, high photochemical stability, long fluorescence lifetime, and the like, and have been widely applied in the fields of fluorescence labeling, film material of a backlight module in a liquid crystal display, and so on.

A color film (CF) substrate is an important component of the display panel in the liquid crystal display, and generally comprises a transparent substrate as well as a black matrix layer and a color filter layer arranged on the transparent substrate. The color filter layer is primarily prepared by a color photoresist. The color photoresist mainly comprises an alkali-soluble resin, a photosensitive resin, a pigment, a photoinitiator, a solvent, etc. However, it is revealed by research that the color filter layer formed from the photosensitive resin and the pigment has a narrow color gamut, which tends to cause a color bleeding phenomenon in the color film substrate.

### SUMMARY

During realization of the present invention, the inventor has discovered that the prior art at least suffers from the following problems. When QDs are mixed with the photoinitiator, a fluorescence quenching phenomenon would occur. Therefore, there is a demand in the art for alleviating or eliminating such fluorescence quenching phenomenon.

Embodiments of the present invention are directed to solve one or more of the above problems. Specifically, embodiments of the present invention are directed to alleviate or eliminate the fluorescence quenching phenomenon in the color photoresist. To this end, embodiments of the present invention provide a color photoresist comprising quantum dots capable of emitting light normally and its use, a color film substrate, a display panel and a liquid crystal display.

On the basis that QDs, when used as the film material of the backlight module in the liquid crystal display, have the characteristics of extending the color gamut and improving the picture quality of the liquid crystal display, the inventor proposes to use QDs as the photosensitive material of the color filter layer in the color film substrate to prevent fluorescence quenching in the color photoresist, thereby extending the color gamut of the liquid crystal display supported by the color film substrate.

In a first aspect, embodiments of the present invention provide a color photoresist comprising a photoinitiator and QDs. The photoinitiator is a first photoinitiator containing no electron-rich group or a second photoinitiator containing an electron-rich group.

The second photoinitiator comprises a conjugation structure, and the conjugation structure consist of the electron-rich group and an adjacent group of the electron-rich group.

For example, the number of electron-rich group in the second photoinitiator is 1 or 2.

For example, the second photoinitiator is of a full-conjugation molecular structure.

For example, in the second photoinitiator, the electron-rich group is coplanar with the adjacent group of the electron-rich group.

For example, all atoms in the second photoinitiator are coplanar.

For example, the second photoinitiator is 1-[4-(phenylthio)phenyl]-1,2-octanedione 2-(O-benzoyloxime), 1-[9-ethyl-6-(2-methylbenzoyl)-9H-carbazol-3-yl]ethanone 1-(O-acetyloxime) or dibenzoyl peroxide.

For example, the first photoinitiator is at least one of benzophenone, 4-phenylbenzophenone and 4-methylbenzophenone.

For example, the color photoresist comprises 1-20% by mass of the quantum dots, 1-3% by mass of the photoinitiator, 1-15% by mass of a crosslinking agent, 5-40% by mass of an alkali-soluble resin, and a balance of a solvent.

For example, the crosslinking agent is an ethylene unsaturated monomer or propylene unsaturated monomer.

For example, the alkali-soluble resin is a (methyl) acrylic acid copolymer resin or esterified styrene/maleic anhydride copolymer resin.

For example, the solvent is propylene glycol methyl ether acetate.

For example, the color photoresist further comprises 1-3% of an adjuvant which is at least one of a stabilizer, a leveling agent, a defoamer, an anticratering agent, an adhesion promoter and a surface slipping agent.

In a second aspect, embodiments of the present invention provide use of the above color photoresist in the preparation of a color film substrate for a liquid crystal display.

In a third aspect, embodiments of the present invention provide a color film substrate which is prepared by using the above color photoresist.

In a fourth aspect, embodiments of the present invention provide a display panel comprising the above color film substrate.

In a fifth aspect, embodiments of the present invention provide a liquid crystal display comprising the above display panel.

The color photoresist provided by embodiments of the present invention comprises a photoinitiator and QDs. When the photoinitiator does not contain an electron-rich group, no rich electron would transfer to the hole trajectory of QDs, ensuring that luminescence quenching would not occur in the QDs. When the photoinitiator contains an electron-rich group, the electron-rich group and its adjacent group constitute a conjugation structure such that the electron-rich group undergoes electron cloud delocalization on its own structure to improve its stability, and does not transfer to the hole trajectory of QDs, which further ensures that QDs do not suffer from fluorescence quenching and emit light normally. In this way, the resultant color photoresist contains QDs which emit light normally, and the color film substrate prepared by using the color photoresist would have a high color gamut, which can effectively improve the picture quality of the liquid crystal display.

### BRIEF DESCRIPTION OF DRAWINGS

In order to set forth the technical solutions in embodiments of the present invention more clearly, the drawings needed for describing embodiments are simply introduced below. Obviously, the drawings described below are only to set forth some embodiments of the present invention, and shall not be regarded as any limitation to the concept of the present invention.

FIG. 1 is a schematic diagram showing change in the fluorescence intensities of the QDs in the color photoresists of Examples 1, 3 and 4 and the Comparative Example since the QDs are mixed with the photoinitiators to form color photoresists until the time for exposure of the color photoresists is extended, in a color filter layer prepared by Example 5 of the present invention.

### DETAILED DESCRIPTION OF EMBODIMENTS

Unless defined otherwise, all the technical terms used in embodiments of the present application have the same meanings as commonly understood by persons having ordinary skill in the art. To make the objectives, technical solutions and advantages of the present invention clearer, embodiments of the present invention will be further described in detail below with reference to the drawings.

The inventor finds based on research that, at the time of preparing a color photoresist comprising QDs, if the used photoinitiator comprises rich electrons, the rich electrons would transfer to a hole trajectory of QDs, that is, the rich electrons would be captured by surface traps of the QDs, such that normal recombination of electroluminescent electrons e⁻ with electroluminescent holes h⁺ is blocked, thereby resulting in luminescence quenching of the QDs. On such basis, it is quite necessary to provide a photoinitiator containing no rich electron or a photoinitiator containing rich electrons which are as few as possible and are very stable.

In a first aspect, embodiments of the present invention provide a color photoresist comprising a photoinitiator and QDs. The photoinitiator is a first photoinitiator containing no electron-rich group or a second photoinitiator containing an electron-rich group. The second photoinitiator comprises a conjugation structure, and the conjugation structure consists of the electron-rich group and an adjacent group of the electron-rich group.

Embodiments of the present invention provide a color photoresist comprising a photoinitiator and QDs. When the photoinitiator does not contain an electron-rich group, no rich electron would transfer to the hole trajectory of QDs, ensuring that luminescence quenching would not occur in the QDs. When the photoinitiator contains an electron-rich group, the electron-rich group and its adjacent group constitute a conjugation structure such that the electron-rich group undergoes electron cloud delocalization on its own structure to improve its stability, without transferring to the hole trajectory of QDs, which further ensures that luminescence quenching would not occur in the QDs such that they can emit light normally. In this way, the resultant color photoresist contains QDs which emit light normally, and the color film substrate prepared by using the color photoresist would have a high color gamut, which can effectively improve the picture quality of the liquid crystal display.

In an embodiment, the first photoinitiator is a common photoinitiator in the art which does not contain a rich electron or an electron-rich group. In an exemplary embodiment, the first photoinitiator is benzophenone, 4-phenylbenzophenone, 4-methylbenzophenone, etc.

In an exemplary embodiment, the number of electron-rich groups in the second photoinitiator is 1 or 2. Embodiments of the present invention ensure that the second photoinitiator contains as few rich electrons as possible by limiting the number of electron-rich groups in the second photoinitiator as above, which further decreases the probability of luminescence quenching of the QDs in the color photoresist.

In an exemplary embodiment, the second photoinitiator is of a full-conjugation molecular structure. In embodiments of the present invention, by limiting the second photoinitiator as a full-conjugation molecular structure, it is ensured that the rich electrons undergo better electron cloud delocalization on their own structures. The rich electrons would be more stable, and would not transfer to the hole trajectory of QDs, thereby ensuring that luminescence quenching would not occur in the QDs and that the QDs emit light normally.

Further, in the second photoinitiator, the electron-rich group is coplanar with the adjacent group of the electron-rich group. In an exemplary embodiment, all atoms in the second photoinitiator are coplanar. In embodiments of the present invention, by limiting the second photoinitiator as above, the rich electrons are enabled to have better delocalizing property. The rich electrons would not transfer to the hole trajectory of QDs, which ensures that luminescence quenching would not occur in the QDs and that the QDs emit light normally.

It is understood that the second photoinitiator is a common photoinitiator in the art which has the structure as defined above. In consideration of low cost and durability, the second photoinitiator is 1-[4-(phenylthio)phenyl]-1,2-octanedione 2-(O-benzoyloxime), 1-[9-ethyl-6-(2-methylbenzoyl)-9H-carbazol-3-yl]ethanone 1-(O-acetyloxime) or dibenzoyl peroxide. In an exemplary embodiment, the second photoinitiator is 1-[9-ethyl-6-(2-methylbenzoyl)-9H-carbazol-3-yl]ethanone 1-(O-acetyloxime) or dibenzoyl peroxide. In an exemplary embodiment, the second photoinitiator is 1-[9-ethyl-6-(2-methylbenzoyl)-9H-carbazol-3-yl]ethanone 1-(O-acetyloxime). Specific information of these three second photoinitiators is shown in Table 1.

TABLE 1

| Trade | | | |
|---|---|---|---|
| Name | Chemical Name | CAS Number | Molecular Structure |
| OXE01 | 1-[4-(phenylthio)phenyl]- 1,2-octanedione 2-(O-benzoyloxime) | 253585-83-0 | 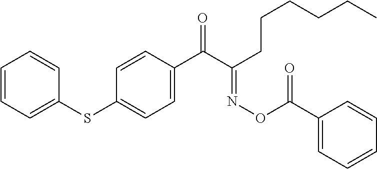 [SMILES: CCCCCC/C(=N\OC(=O)c1ccccc1)C(=O)c1ccc(Sc2ccccc2)cc1] |
| OXE02 | 1-[9-ethyl-6-(2-methyl- benzoyl)-9H-carbazol-3-yl] ethanone 1-(O-acetyloxime) | 478556-66-0 | 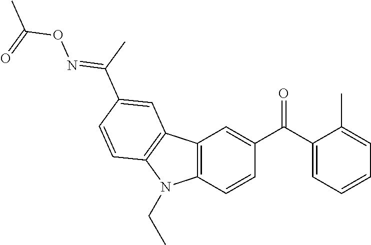 [SMILES: CCn1c2ccc(C(=O)c3ccccc3C)cc2c2cc(/C(C)=N/OC(C)=O)ccc21] |
| BPO | dibenzoyl peroxide | 94-36-0 | 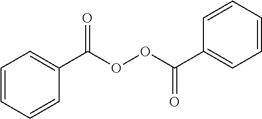 [SMILES: O=C(OOC(=O)c1ccccc1)c1ccccc1] |

Specifically, the photoinitiator 1-[4-(phenylthio)phenyl]-1,2-octanedione 2-(O-benzoyloxime) has the molecular structure as shown in Table 1. It also contains N electron-rich groups, and the N electron-rich groups constitute a conjugation structure with adjacent groups thereof. However, the molecules are not of a coplanar structure due to N=sideward long alkyl chains. Thus, the delocalization of the N rich electrons is not as good as that of N rich electrons in the photoinitiator 1-[9-ethyl-6-(2-methylbenzoyl)-9H-carbazol-3-yl]ethanone 1-(O-acetyloxime), and some of the electrons would transfer, causing that luminescence quenching occurs in some of the QDs. In special cases, the QDs in which partial fluorescence quenching occurs may also continue to be used for preparing the color photoresist.

In addition, the photoinitiator 1-[9-ethyl-6-(2-methylbenzoyl)-9H-carbazol-3-yl]ethanone 1-(O-acetyloxime) has the molecular structure as shown in Table 1, and also contains N electron-rich groups. Since the N electron-rich groups constitute a conjugation structure with adjacent groups thereof, the N rich electrons would undergo electron cloud delocalization on their own structures, and charges would not transfer to the QDs, thereby enabling the QDs to emit light normally.

Specifically, in the color photoresist in embodiments of the present invention, the QDs are at least one of red QDs, blue QDs and green QDs. For example, the QDs is Si QDs, Ge QDs, InAs QDs, GaSb QDs, GaN QDs, ZnTe QDs, CdSe QDs, CdTe QDs, ZnSe QDs, CdS QDs, ZnO QDs, SiGe QDs, combinations thereof or core-shell structures thereof. Generally, the QDs in embodiments of the present invention have a particle size about 2-20 nm, e.g., 10-20 nm. It is understood that the fluorescence peak position of the QDs is tuned by adjusting the size of the QDs.

On the basis of the above contents, embodiments of the present invention provide a color photoresist having specific composition and proportion. The color photoresist comprises 1-20% by mass of the QDs, 1-3% by mass of the photoinitiator, 1-15% by mass of a crosslinking agent, 5-40% by mass of an alkali-soluble resin, and a balance of a solvent. The desired color photoresist in embodiments of the present invention can be obtained by mixing the above components homogeneously.

In the color photoresist in embodiments of the present invention, by means of synergistic action between the above components, under the condition of UV light, the photoinitiator can produce free radicals after absorbing light to initiate a crosslinking and curing reaction of the crosslinking agent to form a compact and stable color film. Moreover, the QDs are distributed uniformly in the color film to form light-emitting active dots and emit fluorescent light under illumination. It can be seen that the addition of QDs to the color photoresist can effectively extend the color gamut of the formed high polymer thin film, and also bring about advantages of wide and continuously distributed excitation spectrums, narrow and symmetrical emission spectrums, tunable color, high photochemical stability, long fluorescence lifetime, and the like.

Specifically, the crosslinking agent used in embodiments of the present invention is an ethylene unsaturated monomer or propylene unsaturated monomer. For example, the ethylene unsaturated monomer or propylene unsaturated monomer has a degree of functionality greater than or equal to 1.

The crosslinking agent in embodiments of the present invention is initiated for polymerization by the free radicals under UV light and undergoes light crosslinking and curing reaction to form a high polymer, thereby forming a compact color film. In order to improve the crosslinking performance of the crosslinking agent, both the ethylene unsaturated monomer and the propylene unsaturated monomer have the following structural unit,

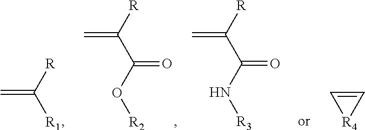

wherein R is hydrogen or methyl;

R₁ is phenyl, hydroxyphenyl, methylphenyl, ethylphenyl, naphthyl or nitrile group;

both R₂ and R₃ are alkyl with 1-8 carbon atoms, hydroxyalkyl with 1-8 carbon atoms, dialkylaminoalkyl, phenyl, benzyl or lauryl, where alkyl in the dialkylaminoalkyl comprises 1-8 carbon atoms;

R₄ is alkyl with 3-8 carbon atoms.

For instance, the crosslinking agent in embodiments of the present invention is at least one of the following substances: monofunctional (methyl) acrylates such as (methyl) methacrylate, (methyl) ethyl acrylate, (methyl) propyl acrylate, (methyl) butyl acrylate, (methyl) 2-hydroxyethyl acrylate, (methyl) lauryl acrylate, glycidyl methacrylate, and mono polyethylene (meth)acrylate; difunctional (methyl) acrylates such as 1,3-butanediol di(meth)acrylate, 1,4-butanediol di(meth)acrylate, 1,6-hexanediol di(meth)acrylate, glycerol di(meth)acrylate, tri(propylene glycol) diacrylate, hexanediol diacrylate, polyethyleneglycol 200 di(meth)acrylate, polyethyleneglycol 400 di(meth)acrylate, and polyethyleneglycol 600 di(meth)acrylate; trifunctional (methyl) acrylates such as glycerol tri(meth)acrylate, pentaerythritol monohydroxy tri(meth)acrylate, trimethylolpropane tri(meth)acrylate, and ethoxylated trimethylolpropane tri(meth)acrylate; tetrafunctional (methyl) acrylates such as pentaerythritol tetraacrylate; polyfunctional (methyl) acrylates such as dipentaerythritol monohydroxy penta(meth)acrylate, and dipentaerythritol monohydroxy hexa(meth)acrylate; styrene, hydroxystyrene, α-methylstyrene, vinyl toluene, vinyl naphthalene, vinyl xylene, divinylbenzene, divinyl toluene, divinyl naphthalene, divinyl pyridine, divinyl silane, trivinyl silane, dimethyldivinylsilane, divinylmethylsilane, methyltrivinylsilane, divinylphenylsilane, trivinylphenylsilane, trivinylsilane, tetravinylsilane, poly(methylvinylsiloxane), poly(vinylhydrosiloxane), etc, but it is not limited to the above compounds.

Specifically, the alkali-soluble resin is a (methyl) acrylic acid copolymer resin or esterified styrene/maleic anhydride copolymer resin.

In order to use an alkaline developer during the subsequent developing process to wash the uncured color film for the purpose of development, embodiments of the present invention use an alkali-soluble resin having carboxylic groups to enable the carboxylic groups to react with the alkaline solution during the developing process to generate water-soluble salts such that the alkali-soluble resin are dissolved in the alkaline developer (e.g. KOH, NaHCO₃, Na₂CO₃, TMAH (tetramethylammonium hydroxide). On such basis, embodiments of the present invention use the (methyl) acrylic acid copolymer resin or esterified styrene/maleic anhydride copolymer resin as the alkali-soluble resin. More specifically, the (methyl) acrylic acid copolymer resin is obtained by copolymerization of an ethylene unsaturated monomer or propylene unsaturated monomer with (methyl) acrylic acid. The (methyl) acrylic acid copolymer resin has a weight-average molecular weight (abbreviated as Mw) of 10,000 to 200,000, e.g., 50,000 to 150,000. Since the alkali-soluble resin has an appropriate acid value, it is ensured that there are sufficient carboxylic groups to react with the alkaline solution during the developing process such that the color film which has not been cured by UV can be washed by the developer for the purpose of development. The acid value as used herein indicates the weight (mg) of potassium hydroxide required for neutralizing free fatty acids contained in 1 gram of fat, fatty oil or other similar substances, and has an unit of mgKOH/g. Based on this, in embodiments of the present invention, the acid value of the (methyl) acrylic acid copolymer resin is kept at 50-250 mgKOH/g, e.g., 100-200 mgKOH/g.

It is understood by a person having ordinary skill in the art that the solvent in embodiments of the present invention is known in the art. By using the solvent, other ingredients can be dissolved and mixed homogeneously such that the prepared color film has a desired viscosity, which facilitates spraying, roll coating or screen printing to the transparent substrate. For instance, the solvent is at least one of the following substances: ester solvents such as ethylene glycol monomethyl ether acetate, ethylene glycol monoethyl ether acetate, ethylene glycol monobutyl ether acetate, diethylene glycol monomethyl ether acetate, ethylene glycol monoethyl ether acetate, ethylene glycol monobutyl ether acetate, propylene glycol monomethyl ether acetate, propylene glycol monoethyl ether acetate or propylene glycol monobutyl ether acetate, ethyl acetate, and butyl acetate; ether solvents such as ethylene glycol monomethyl ether, ethylene glycol monoethyl ether, ethylene glycol monobutyl ether, diethylene glycol monomethyl ether, ethylene glycol monoethyl ether, ethylene glycol monobutyl ether, propylene glycol monomethyl ether, and dipropylene glycol monomethyl ether; alcohol solvents such as n-propyl alcohol, isopropanol, butyl alcohol and isobutanol; ketone solvents such as butanone, cyclohexanone and isophorone; aromatic solvents such as toluene and xylene; petroleum solvents such as naphtha, oxidized naphtha, and solvent naphtha. In an exemplary embodiment, the solvent is propylene glycol monomethyl ether acetate, ethylene glycol monoethyl ether acetate, butanone, and dipropylene glycol monomethyl ether, but it is not limited to the above compounds. In an exemplary embodiment, the solvent is propylene glycol methyl ether acetate.

Further, in order to improve the comprehensive performance of the prepared color film, in embodiments of the present invention, the color photoresist further comprises 1-3% of an adjuvant, wherein the adjuvant is at least one of a stabilizer, a leveling agent, a defoamer, an anticratering agent, an adhesion promoter and a surface slipping agent, thereby making the prepared color film more compact, smooth, and stronger adhesion.

In a second aspect, embodiments of the present invention provide use of the above color photoresist in the preparation of a color film substrate for a liquid crystal display.

By preparing a color film substrate for a liquid crystal display with the color photoresist in embodiments of the present invention, the resultant color film substrate has a higher color gamut, which is advantageous to improvement of the picture quality of the liquid crystal display. It is be understood that the method for preparation of a color film substrate by using the color photoresist, more specifically for preparation of a color filter layer, is commonly known by the person having ordinary skill in the art.

For example, the color filter layer is prepared with the color photoresist by a method comprising the following steps.

Step 101, the color photoresist in embodiments of the present invention is subject to film forming treatment by spin-coating to form a liquid film with a thickness of 2-10 μm. For example, the thickness of the liquid film is 2-5 μm, 4-7 μm, 6-9 μm, 5.5 μm, 6.5 μm, 7.5 μm, 8.5 μm, 9.5 μm, etc.

Step 102, the liquid film formed in step 101 is subject to exposure treatment using UV light to obtain a cured color film. The used UV light has a wavelength of 365 nm, and the energy for exposure is 50-500 MJ/cm², e.g., 100 MJ/cm².

Step 103, the cured color film obtained in step 102 is subject to developing treatment by using an alkaline developer so as to remove the alkali-soluble resin therein to obtain a patterned color film. In an exemplary embodiment, the alkaline developer is a potassium hydroxide solution, and the developing time is 30-100 s, e.g., 50 s.

Step 104, the patterned color film obtained in step 103 is washed by water and then dried. During drying, the temperature for drying is 100-250° C., e.g., 150° C., and the time for drying is 20-60 minutes, e.g., 30 minutes.

In a third aspect, embodiments of the present invention provide a color film substrate. The color film substrate is prepared by using the above color photoresist provided by embodiments of the present invention.

The color film substrate in embodiments of the present invention has the characteristic of high color gamut since it uses the color photoresist containing QDs, and is advantageous to improvement of the picture quality of the liquid crystal display when used in the liquid crystal display.

In a fourth aspect, embodiments of the present invention provide a display panel. The display panel comprises the above color film substrate provided by embodiments of the present invention. It is be understood that using the color film substrate for preparation of a display panel is an existing technique commonly used in the art, which is not specifically defined here by embodiments of the present invention.

In a fifth aspect, embodiments of the present invention provide a liquid crystal display. The liquid crystal display comprises the above display panel provided by embodiments of the present invention. It is understood that using the display panel for preparation of a liquid crystal display is an existing technique commonly used in the art, which is not specifically defined here by embodiments of the present invention.

The present invention will be further described below by virtue of specific examples.

In the following specific examples, the involved operations for which conditions are not specified are all performed according to conventional conditions or conditions suggested by the manufacturer. The raw materials whose manufacturers or specifications are not marked are conventional available products.

### EXAMPLE 1

The present example provides a color photoresist comprising components of 5% by mass of QDs, 1% by mass of a photoinitiator, 4% by mass of a crosslinking agent, 20% by mass of an alkali-soluble resin, and a balance of a solvent.

The QDs are spherical CdTe QDs having an average particle size of 10 nm. The photoinitiator is 1-[4-(phenylthio)phenyl]-1,2-octanedione 2-(O-benzoyloxime). The crosslinking agent is (methyl) methacrylate. The alkali-soluble resin is an acrylic acid copolymer resin (which is formed by copolymerization of 20% by mass of acrylic acid and 80% by mass of methyl methacrylate, and has a weight-average molecular weight of 100,000, a molecular weight distribution index of 1.93, and an acid value of 180 mgKOH/g). The solvent is ethylene glycol monoethyl ether acetate.

### EXAMPLE 2

The present example provides a color photoresist comprising components of 10% by mass of QDs, 2% by mass of a photoinitiator, 5% by mass of a crosslinking agent, 30% by mass of an alkali-soluble resin, and a balance of a solvent.

The QDs are spherical CdS QDs having an average particle size of 10 nm. The photoinitiator is benzophenone. The crosslinking agent is (methyl) ethyl acrylate. The alkali-soluble resin is a copolymer of 10 parts by weight of an acrylic acid copolymer resin (which is formed by copolymerization of 10% by mass of acrylic acid, 50% by mass of methyl methacrylate and 40% of n-octyl acrylate, and has a weight-average molecular weight of 50,000, a molecular weight distribution index of 2.10, and an acid value of 100 mgKOH/g) and 30 parts by weight of 2-butyl alcohol-esterified styrene maleic anhydride, and has a weight-average molecular weight of 60,000 and an acid value of 150 mgKOH/g. The solvent is propylene glycol monomethyl ether acetate.

### EXAMPLE 3

The present example provides a color photoresist comprising components of 20% by mass of QDs, 3% by mass of a photoinitiator, 5% by mass of a crosslinking agent, 40% by mass of an alkali-soluble resin, and a balance of a solvent.

The QDs are spherical SiGe QDs having an average particle size of 15 nm. The photoinitiator is dibenzoyl peroxide. The crosslinking agent is (methyl) propyl acrylate. The alkali-soluble resin is 2-butyl alcohol-esterified styrene maleic anhydride copolymer resin (with a weight-average molecular weight of 30,000, a molecular weight distribution index of 2.03, and an acid value of 170 mgKOH/g). The solvent is dipropylene glycol monomethyl ether.

### EXAMPLE 4

The present example provides a color photoresist comprising components of 15% by mass of QDs, 2.5% by mass of a photoinitiator, 4.5% by mass of a crosslinking agent, 25% by mass of an alkali-soluble resin, and a balance of a solvent.

The QDs are spherical CdSe QDs having an average particle size of 8 nm. The photoinitiator is 1-[9-ethyl-6-(2-methylbenzoyl)-9H-carbazol-3-yl]ethanone 1-(O-acetyloxime). The crosslinking agent is 1,3-butanediol di(meth)acrylate. The alkali-soluble resin is a copolymer of 30 parts by weight of an acrylic acid copolymer resin (which is formed by copolymerization of 20% acrylic acid and 80% methyl methacrylate, and has a weight-average molecular weight of 100,000, a molecular weight distribution index of 1.93, and an acid value of 180 mgKOH/g) and 20 parts by weight of 2-butyl alcohol-esterified styrene maleic anhydride, and has a weight-average molecular weight of 24,000 and an acid value of 150 mgKOH/g. The solvent is propylene glycol methyl ether acetate.

### COMPARATIVE EXAMPLE

The present comparative example provides a color photoresist comprising components of 15% by mass of QDs, 2.5% by mass of a photoinitiator, 4.5% by mass of a crosslinking agent, 25% by mass of an alkali-soluble resin, and a balance of a solvent.

The QDs are spherical CdSe QDs having an average particle size of 8 nm. The photoinitiator is 2-benzyl-2-dimethylamino-1-(4-phenylmorpholine)butanone. The crosslinking agent is 1,3-butanediol di(meth)acrylate. The alkali-soluble resin is a copolymer of 30 parts by weight of an acrylic acid copolymer resin (which is formed by copolymerization of 20% acrylic acid and 80% methyl methacrylate, and has a weight-average molecular weight of 100,000, a molecular weight distribution index of 1.93, and an acid value of 180 mgKOH/g) and 20 parts by weight of 2-butyl alcohol-esterified styrene maleic anhydride, and has a weight-average molecular weight of 24,000 and an acid value of 150 mgKOH/g. The solvent is propylene glycol methyl ether acetate.

The trade name of 2-benzyl-2-dimethylamino-1-(4-phenylmorpholine)butanone is 369, the CAS number thereof is 119313-12-1, and the molecular structure thereof is shown as follows:

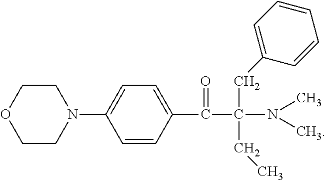 [SMILES: CCC(Cc1ccccc1)(C(=O)c1ccc(N2CCOCC2)cc1)N(C)C]

### EXAMPLE 5

The present example prepares the color filter layer in the color film substrate using the color photoresists provided by Examples 1-4 and the Comparative Example, respectively. The method comprises the following steps.

Step a, the color photoresist of the above examples is subject to film forming treatment by spin-coating to form a liquid film having a thickness of 5 μm.

Step b, the resulting liquid film in step a is subject to exposure treatment by UV light to provide a cured color film. The used UV light has a wavelength of 365 nm, and the energy for exposure is 100 MJ/cm².

Step c, the cured color film in step b is subject to developing treatment by an alkaline developer so as to remove the alkali-soluble resin therein and provide a patterned color film. For example, the alkaline developer is a potassium hydroxide solution, and the developing time is 50 s.

Step d, the patterned color film in step c is washed with water and then dried. During drying, the temperature for drying is 150° C., and the time for drying is 30 minutes.

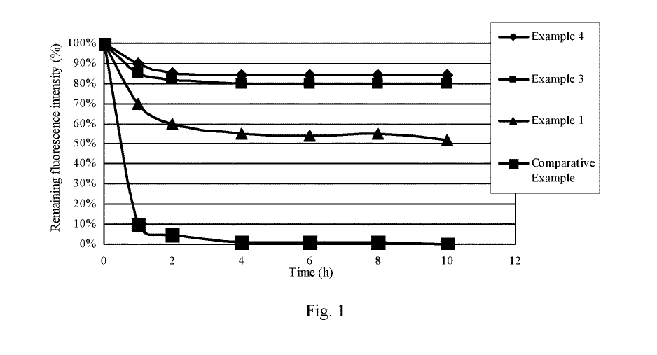

The fluorescence intensities of the QDs in the color photoresists provided by Examples 1-4 and the Comparative Example are observed. Specifically, during the process of formulating the respective color photoresists, the fluorescence intensities of the QDs are observed when the QDs are mixed with the photoinitiator. Thereafter, after the color photoresists have been exposed for 3 seconds, the fluorescence intensities of the QDs contained therein are observed. The results of change in the fluorescence intensities of the QDs are shown in Table 2 and FIG. 1, respectively.

TABLE 2

| | Fluorescence intensity | |
|---|---|---|
| | After mixture of QDs | After exposure of color |
| Color photoresist | with photoinitiator | photoresist for 3 seconds |
| Example 1 | Bright | Slightly dimmed |
| Example 2 | Bright | Bright |
| Example 3 | Bright | Bright |
| Example 4 | Bright | Bright |
| Comparative | Slightly dimmed | Apparently dimmed |
| Example | | |

It is known from Table 2 that after the QDs in the color photoresists from Examples 1-4 are mixed with the photoinitiator, the fluorescence intensities of the QDs substantially do not change, and that after the color photoresists have been exposed for 3 seconds, only the QDs in Example 1 are slightly dimmed. Namely, partial luminescence quenching occurs in the QDs of Example 1, but these color photoresists can still be used for preparing the color film substrate. However, after the color photoresists in Examples 2-4 have been exposed for 3 seconds, the intensities of the QDs do not change, i.e. luminescence quenching does not occur in these QDs. These color photoresists can be effectively used for preparing the color film substrate with high color gamut. However, in the color photoresist provided by the Comparative Example, after the QDs are mixed with the photoinitiator, the fluorescence intensity of the QDs is slightly dimmed, and after the color photoresist has been exposed for 3 seconds, a significant luminescence quenching phenomenon appears in the QDs. This color photoresist cannot be used for preparing the color film substrate.

Also, as shown in FIG. 1, as the time for exposure of the color photoresists is extended from the moment the QDs are mixed with the photoinitiator to form the color photoresists, the fluorescence intensities of the QDs in Examples 1, 3 and 4 show an initial decrease by about 20% and then become stable. When the photoinitiator is 1-[9-ethyl-6-(2-methylbenzoyl)-9H-carbazol-3-yl]ethanone 1-(O-acetyloxime) (corresponding to Example 4), the QDs show the smallest decrease in the fluorescence intensity, and the luminescent property of the QDs is optimal. When the photoinitiator is 2-benzyl-2-dimethylamino-1-(4-phenylmorpholine)butanone (corresponding to the Comparative Example), the QDs show the largest decrease in the fluorescence intensity up to complete quenching.

In conclusion, none of the photoinitiators provided by Examples 1-4 of the present invention would cause a significant luminescence quenching phenomenon in the QDs, and the color photoresists prepared by mixing the photoinitiators with the QDs can all be used for preparing the color film substrate with high color gamut.

### EXAMPLE 6

The present example prepares liquid crystal displays using the color photoresists provided by Examples 1-4 and the Comparative Example, respectively. The prepared liquid crystal displays comprise a backlight and a liquid crystal display panel. The liquid crystal display panel comprises a color film substrate, and the color film substrate comprises a transparent substrate, and a black matrix layer and a color filter layer arranged on the transparent substrate. Specifically, the color filter layers are prepared by the color photoresists from Examples 1-4 and the Comparative Example, respectively. Then, the color gamut performances of the above liquid crystal displays are tested, and the results are shown in Table 3.

TABLE 3

| Color photoresist used in | Color gamut of liquid |
|---|---|
| liquid crystal display | crystal display |
| Example 1 | 130% |
| Example 2 | 125% |
| Example 3 | 127% |
| Example 4 | 135% |

As can be known from Table 3, the liquid crystal displays prepared by using the color photoresists provided by the examples of the present invention have a high color gamut which can efficiently improve the picture quality of the liquid crystal display and is advantageous to enhancement of the user's comfort.

Although the present invention has been described with reference to the embodiments currently taken into consideration, it should be understood that the present invention is not limited to the disclosed embodiments. On the contrary, the present invention aims to cover various modifications and equivalent arrangements within the spirit and scope of the appended claims. The scopes of the following claims are subject to the broadest explanations so as to include each of such modifications and equivalent structures and functions.

1. A color photoresist, comprising a photoinitiator and QDs,
wherein the photoinitiator is a first photoinitiator containing no electron-rich group or a second photoinitiator containing an electron-rich group,
the second photoinitiator comprising a conjugation structure, and the conjugation structure consists of the electron-rich group and an adjacent group of the electron-rich group.

2. The color photoresist according to claim 1, wherein in the second photoinitiator, the number of the electron-rich group is 1 or 2.

3. The color photoresist according to claim 2, wherein the second photoinitiator is of a full-conjugation molecular structure.

4. The color photoresist according to claim 1, wherein in the second photoinitiator, the electron-rich group is coplanar with the adjacent group of the electron-rich group.

5. The color photoresist according to claim 4, wherein all atoms in the second photoinitiator are coplanar.

6. The color photoresist according to claim 1, wherein the second photoinitiator is 1-[4-(phenylthio)phenyl]-1,2-octanedione 2-(O-benzoyloxime), 1-[9-ethyl-6-(2-methylbenzoyl)-9H-carbazol-3-yl]ethanone 1-(O-acetyloxime) or dibenzoyl peroxide.

7. The color photoresist according to claim 1, wherein the first photoinitiator is at least one of benzophenone, 4-phenylbenzophenone and 4-methylbenzophenone.

8. The color photoresist according to claim 1, wherein the color photoresist comprises: 1-20% by mass of the QDs, 1-3% by mass of the photoinitiator, 1-15% by mass of a crosslinking agent, 5-40% by mass of an alkali-soluble resin, and a balance of a solvent.

9. The color photoresist according to claim 8, wherein the crosslinking agent is an ethylene unsaturated monomer or propylene unsaturated monomer.

10. The color photoresist according to claim 9, wherein the alkali-soluble resin is a (methyl) acrylic acid copolymer resin or esterified styrene/maleic anhydride copolymer resin.

11. The color photoresist according to claim 10, wherein the solvent is propylene glycol methyl ether acetate.

12. The color photoresist according to claim 8, wherein the color photoresist further comprises 1-3% by mass of an adjuvant, the adjuvant is at least one of a stabilizer, a leveling agent, a defoamer, an anticratering agent, an adhesion promoter and a surface slipping agent.

13. Use of the color photoresist according to claim 1 in the preparation of a color film substrate for a liquid crystal display.

14. A color film substrate, prepared by using the color photoresist according to claim 1.

15. A display panel comprising the color film substrate according to claim 14.

16. A liquid crystal display comprising the display panel according to claim 15.

17. The color photoresist according to claim 2, wherein in the second photoinitiator, the electron-rich group is coplanar with the adjacent group of the electron-rich group.

18. The color photoresist according to claim 9, wherein the color photoresist further comprises 1-3% by mass of an adjuvant, the adjuvant is at least one of a stabilizer, a leveling agent, a defoamer, an anticratering agent, an adhesion promoter and a surface slipping agent.

19. The color photoresist according to claim 10, wherein the color photoresist further comprises 1-3% by mass of an adjuvant, the adjuvant is at least one of a stabilizer, a leveling agent, a defoamer, an anticratering agent, an adhesion promoter and a surface slipping agent.

20. The color photoresist according to claim 11, wherein the color photoresist further comprises 1-3% by mass of an adjuvant, the adjuvant is at least one of a stabilizer, a leveling agent, a defoamer, an anticratering agent, an adhesion promoter and a surface slipping agent.
